(19) United States
(12) Patent Application Publication
(10) Pub. No.: US 2010/0242842 A1
(43) Pub. Date: Sep. 30, 2010

(54) Evaporation system

(75) Inventors: Hideaki Takeuchi, Kanagawa (JP); Junji Nakada, Kanagawa (JP)

Correspondence Address: AKERMAN SENTERFITT, 8100 BOONE BOULEVARD, SUITE 700, VIENNA, VA, 22182-2683, US

(73) Assignee: FUJIFILM Corporation, Tokyo (JP)

(21) Appl. No.: 12/656,886

(22) Filed: Feb. 18, 2010

(30) Foreign Application Priority Data
Mar. 31, 2009 (JP) 2009-088503

(51) Int. Cl. C23C 16/00; C23C 14/34

(52) U.S. Cl. 118/718; 204/298.25

(57) ABSTRACT

An evaporation system for forming evaporation films on a substrate film, includes: a first drive portion which is driven to rotate to thereby feed out the substrate film; a second drive portion which is driven to rotate to thereby take up the substrate film conveyed to the second drive portion; film-forming rollers which are provided on a conveyance path of the substrate film conveyed between the first drive portion and the second drive portion and which support one surface of the substrate film onto circumferential surfaces of the film-forming rollers; evaporation portions which form the evaporation films on a surface of the substrate film opposite to the surface supported by the film-forming rollers; and a third drive portion as defined herein.

### CROSS-REFERENCE TO RELATED APPLICATIONS

This application claims the benefit of Japanese Patent Application JP 2009-088503, filed Mar. 31, 2009, the entire content of which is hereby incorporated by reference, the same as if set forth at length.

### FIELD OF THE INVENTION

The present invention relates to an evaporation system.

### BACKGROUND OF THE INVENTION

An evaporation system used for forming a film on a surface of a substrate is known. In production of a support for a magnetic recording medium, such an evaporation system has been used in recent years for forming an evaporation film containing a metal compound excellent in both water vapor barrier characteristic and Young's modulus on a surface of a plastic substrate film containing a high-molecular material.

A system in which two cans are provided in a vacuum container so that magnetic films are formed by sputtering or vapor deposition on a film conveyed on the cans has been described in JP-A-6-215371.

A film-forming system in which an evaporation portion is provided so that a film is fed to pass through the evaporation portion twice to thereby form films on both surfaces of the film has been described in JP-A-2005-213582. According to this configuration, a take-up shaft need be moved in order to perform vapor deposition on both surfaces of the film, so that it is unavoidable that the configuration of the system is complicated. In addition, there are many restrictions on configuration for enabling the take-up shaft to move.

### SUMMARY OF THE INVENTION

Incidentally, for forming evaporation films, there are the case where evaporation films are formed on both surfaces of a substrate film and the case where a plurality of film-forming materials are laminated on one surface of a substrate film. To use one evaporation system on the assumption of these cases, the evaporation system need to be configured so that a plurality of film-forming rolls are provided. If the evaporation system is configured so that a plurality of film-forming rolls are provided, it is unavoidable that the length of a path for conveying the substrate film becomes so long that the system is large-scaled and complicated. Accordingly, there is room for improvement against increase in equipment cost.

An object of the invention is to provide an evaporation system which can be used for vapor deposition on both surfaces of a substrate film and used also for vapor deposition on one surface of the substrate film while increase in size and complication of the system can be avoided.

The invention provides an evaporation system for forming evaporation films on a substrate film, including: a first drive portion which is driven to rotate to thereby feed out the substrate film; a second drive portion which is driven to rotate to thereby take up the substrate film conveyed to the second drive portion; film-forming rollers which are provided on a conveyance path of the substrate film conveyed between the first drive portion and the second drive portion and which support one surface of the substrate film onto circumferential surfaces of the film-forming rollers; evaporation portions which form the evaporation films on a surface of the substrate film opposite to the surface supported by the film-forming rollers; and a third drive portion which is driven while either of the first drive portion and the second drive portion is changed over to the third drive portion so that the conveyance path is changed to select either of evaporation on both surfaces of the substrate film and evaporation on a single surface of the substrate film in accordance with whether change-over to the third drive portion is made or not.

The evaporation system selects two drive portions (inclusive of the third drive portion) from three drive portions in accordance with the direction of a surface of the substrate film as a target surface of evaporation and performs evaporation on the substrate film in accordance with a conveyance path defined by the selected two drive portions. Here is assumed a configuration in which control can be made so that the first drive portion is changed over to the third drive portion and vice versa. In this case, for example, evaporation can be made on only one surface of the substrate film while the substrate film is conveyed so that the substrate film is fed out from the first drive portion and taken up by the second drive portion, whereas evaporation can be made on both surfaces of the substrate film while the substrate film is conveyed so that the substrate film is fed out from the third drive portion and taken up by the second drive portion. In this manner, the conveyance path is changed to select either evaporation on both surfaces of the substrate film or evaporation on a single surface of the substrate film in accordance with whether the first drive portion is changed over to the third drive portion or not. By changing over the drive portion in this manner, evaporation can be made either on both surfaces of the substrate film or on a desired single surface of the substrate film without the necessity of changing the locations of the film-forming rolls, and the evaporation portions. According to the invention, increase in size and complication of the evaporation system can be therefore avoided, so that increase in equipment cost can be prevented.

According to the invention, it is possible to provide an evaporation system which can be used for vapor deposition on both surfaces of a substrate film and used also for vapor deposition on one surface of the substrate film while increase in size and complication of the system can be avoided.

### BRIEF DESCRIPTION OF THE DRAWINGS

FIGS. 1A and 1B are views showing an example of configuration of an evaporation system.

FIGS. 2A and 2B are views showing another example of configuration of the evaporation system.

FIGS. 3A and 3B are views showing a further example of configuration of the evaporation system.

FIG. 4 is a block diagram for explaining a control system of the evaporation system.

FIG. 5 is a block diagram for explaining a control system of the evaporation system.

### DETAILED DESCRIPTION OF THE INVENTION

An evaporation system will be described below with reference to the drawings.

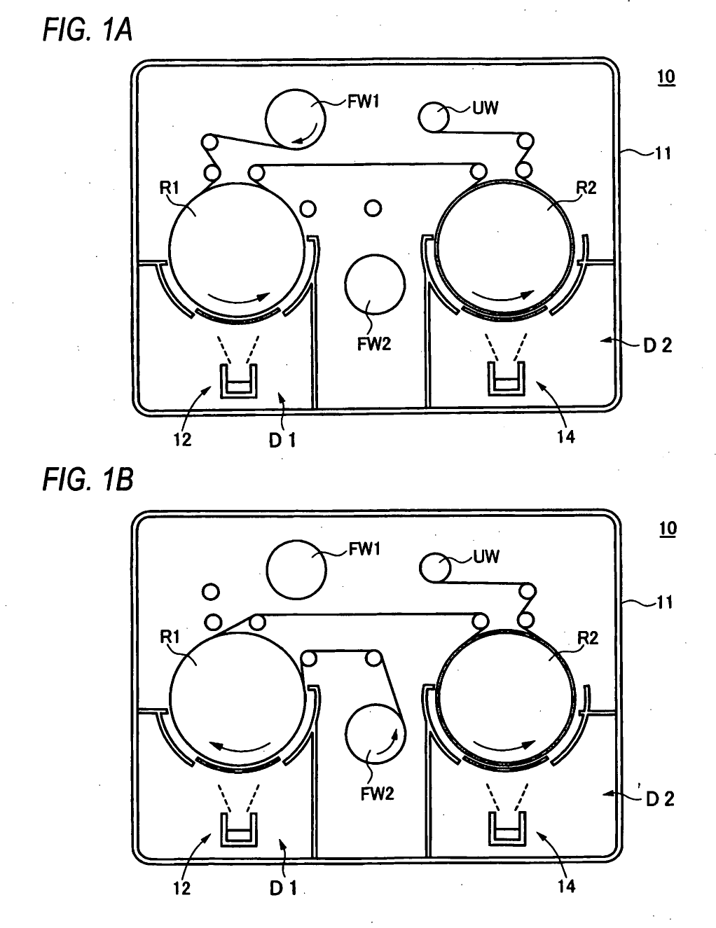

FIGS. 1A and 1B show an example of configuration of an evaporation system for forming evaporation films on a substrate film. FIG. 1A shows a state of conveyance in the case where different evaporation films are laminated on one surface of the substrate film. FIG. 1B shows a state of conveyance in the case where evaporation films are deposited on both surfaces of the substrate film respectively.

The substrate film is a long belt-like member but the material and shape of the substrate film are not particularly limited as long as evaporation films can be formed on the substrate film. In the following description, a substrate film containing a high-molecular material for producing a support of a magnetic recording medium is used as an example.

Increase in recording density of a magnetic recording medium has advanced in recent years, so that there is a demand for higher-level dimensional stability and mechanical strength than those of a conventional magnetic recording medium in order to keep recording/reproduction stable. To obtain high-level dimensional stability of a magnetic recording medium, it is conceived that a bad influence caused by variations in a non-magnetic support of a substrate film used in a magnetic recording medium in accordance with temperature and humidity and variations in tension in a drive is suppressed. To suppress variations in the non-magnetic support in accordance with temperature and humidity, it is conceived that films excellent in water vapor barrier characteristic are provided on both surfaces of the support. To suppress the bad influence caused by variations in tension in a drive, it is conceived that a film with a high Young's modulus is provided. Therefore, an evaporation film containing a metal or a metal compound such as metal oxide or metal nitride is used as a film excellent in both water vapor barrier characteristic and Young's modulus so that the evaporation film is deposited on the support of the magnetic recording medium by the evaporation system.

The evaporation system 10 has a housing 11 in which an inner space is provided for forming evaporation films on a substrate film. The inside of the housing 11 is set to be in a vacuum state.

Drive portions FW1 and FW2 are provided in the housing 11 so that the drive portions FW1 and FW2 can hold the substrate film wound on each of the drive portions FW1 and FW2 and can be driven to rotate to thereby feed out the substrate film at the time of film-forming. A drive portion UW is further provided in the housing 11 so that the drive portion UW can be driven to rotate to thereby take up the substrate film conveyed to the drive portion UW. Each of the drive portions FW1 and FW2 and the drive portion UW has a drive shaft which is driven by motive power transmitted from a motive power source such as a motor not shown.

The evaporation system 10 is formed so that the substrate film fed out from the drive portion FW1 or FW2 is conveyed along a conveyance path and taken up by the drive portion UW. Guide rollers are provided for guiding the conveyed substrate film along the conveyance path. Each of the guide rollers can be provided as a roller which is not driven to rotate. Configuration may be made so that part of the guide rollers can be driven to move back and forth to adjust a pressure applied on a surface of the conveyed substrate film to thereby adjust tension of the substrate film.

Two film-forming rollers R1 and R2 are further provided in the evaporation system 10. Each of the film-forming rollers R1 and R2 is shaped like a column and supports one surface of the substrate film conveyed on a circumferential surface of the film-forming roller R1, R2.

Assuming now that the feed-out side of the substrate film is an upstream side and the take-up side of the substrate film is a downstream side in terms of the conveyance path, then the film-forming roller R1 is disposed on the upstream side in comparison with the film-forming roller R2.

The film-forming roller R1 is partially located in the inside of an evaporation chamber D1. An evaporation portion 12 is provided in the inside of the evaporation chamber D1. The substrate film is conveyed while supported by the film-forming roller R1, so that the evaporation portion 12 in the inside of the evaporation chamber D1 forms an evaporation film on a surface of the substrate film opposite to the surface supported by the film-forming roller R1.

The film-forming roller R2 is partially located in the inside of an evaporation chamber D2. An evaporation portion 14 is provided in the inside of the evaporation chamber D2. The substrate film is conveyed while supported by the film-forming roller R2, so that the evaporation portion 14 in the inside of the evaporation chamber D2 forms an evaporation film on a surface of the substrate film opposite to the surface supported by the film-forming roller R2.

The evaporation chambers D1 and D2 are isolated from each other by partition walls or the like provided between each evaporation chamber D1, D2 and a space for conveying the substrate film in the housing 11.

Each of the evaporation portions 12 and 14 contains an evaporation material and forms a thin film in such a manner that the evaporation material is heated by a heating unit such as a resistor, a heater, etc. at the time of evaporation so as to be vaporized or sublimated to thereby be deposited on a surface of the substrate film conveyed to the evaporation portion 12, 14.

In this example of configuration, two drive portions FW1 and FW2 for feeding out the substrate film and one drive portion UW for taking up the substrate film are provided. One of the drive portions FW1 and FW2 is changed over to the other so that the substrate film can be conveyed in such a manner that the substrate film is fed out from either of the drive portions FW1 and FW2 and taken up by the drive portion UW. According to this configuration, it is possible to set two conveyance paths, that is, a conveyance path on which the substrate film is conveyed in such a manner that the substrate film is fed out from the drive portion FW1 and taken up by the drive portion UW as shown in FIG. 1A and a conveyance path on which the substrate film is conveyed in such a manner that the substrate film is fed out from the drive portion FW2 and taken up by the drive portion UW as shown in FIG. 1B.

The drive portions FW1 and FW2 can be controlled to be driven respectively independently. The directions of rotation at the time of driving can be controlled respectively.

There are two cases for forming a plurality of evaporation films on the substrate film. One is the case where different evaporation films are laminated on one surface of the substrate film. The other is the case where evaporation films are formed on both surfaces of the substrate film respectively. To configure one evaporation system capable of performing evaporation on both surfaces of the substrate film and also capable of performing evaporation on a signal surface of the substrate film, increase in size and complication of the system could not be avoided because it was necessary not only to provide a complicated conveyance switching configuration but also to change the locations of the film-forming rollers and the evaporation portions. In the evaporation system according to this example of configuration, one of the two drive portions FW1 and FW2 in the three drive portions FW1, FW2 and UW can be changed over to the other so that evaporation can be made on a desired surface of the substrate film without change of the locations of the film-forming rollers R1 and R2 and the evaporation portions 12 and 14.

FIG. 1A shows a state in which evaporation is made twice on a single surface of the substrate film. Specifically, the drive portion FW1 is driven to rotate to thereby feed out the substrate film along the conveyance path. On this occasion, the drive portion FW2 is not driven to rotate at all or is driven to rotate in such a range as to exert no influence on the conveyed substrate film. One surface of the substrate film is supported by the film-forming roller R1, so that the evaporation portion 12 in the evaporation chamber D1 forms an evaporation film on a surface of the substrate film opposite to the surface supported by the film-forming roller R1.

Then, the surface of the substrate film supported by the film-forming roller R1 is supported by the film-forming roller R2. The evaporation portion 14 in the evaporation chamber D2 forms an evaporation film on a surface of the substrate film opposite to the surface supported by the film-forming roller R2. Then, the substrate film is taken up by the drive portion UW.

By conveying the substrate film as shown in FIG. 1A, evaporation can be made twice on a single surface of the substrate film.

For example, a film containing a metal or a metal compound (such as metal oxide or metal nitride) can be vapor-deposited on a surface of the substrate film by the evaporation portion 12, and a film containing an organic material can be further vapor-deposited on the surface of the substrate film by the evaporation portion 14. According to this configuration, the substrate film can be brought into sufficient contact with each film-forming roller so that the plastic substrate film can be prevented from being thermally damaged by a heat load such as heat radiated from each evaporation source at the time of evaporation or heat of condensation at the time of evaporation even when the substrate film is conveyed at a relatively high speed. As a result, good-quality evaporation films can be formed.

FIG. 1B shows a state in which evaporation is made on both surfaces of the substrate film. Specifically, the drive portion FW2 is driven to rotate to thereby feed out the substrate film along the conveyance path. On this occasion, the drive portion FW1 is not driven to rotate at all or is driven to rotate in such a range as to exert no influence on the conveyed substrate film. One surface of the substrate film is supported by the film-forming roller R1. A surface of the substrate film opposite to the surface supported by the film-forming roller R1 is used as a target surface of evaporation so that the evaporation portion 12 in the evaporation chamber D1 forms an evaporation film on the target surface of evaporation.

Then, the surface of the substrate film supported by the film-forming roller R1 is used as a target surface of evaporation by the film-forming roller R2 so that the evaporation portion 14 in the evaporation chamber D2 forms an evaporation film on the surface of the substrate film. Then, the substrate film is taken up by the drive portion UW.

By conveying the substrate film as shown in FIG. 1B, evaporation can be made on both surfaces of the substrate film.

For example, films each containing a metal or a metal compound (such as metal oxide or metal nitride) can be vapor-deposited on both surfaces of the substrate film by the evaporation portions 12 and 14 respectively. According to this configuration, water vapor barrier characteristic of the substrate film can be improved so that the Young's modulus of the substrate film can be kept high.

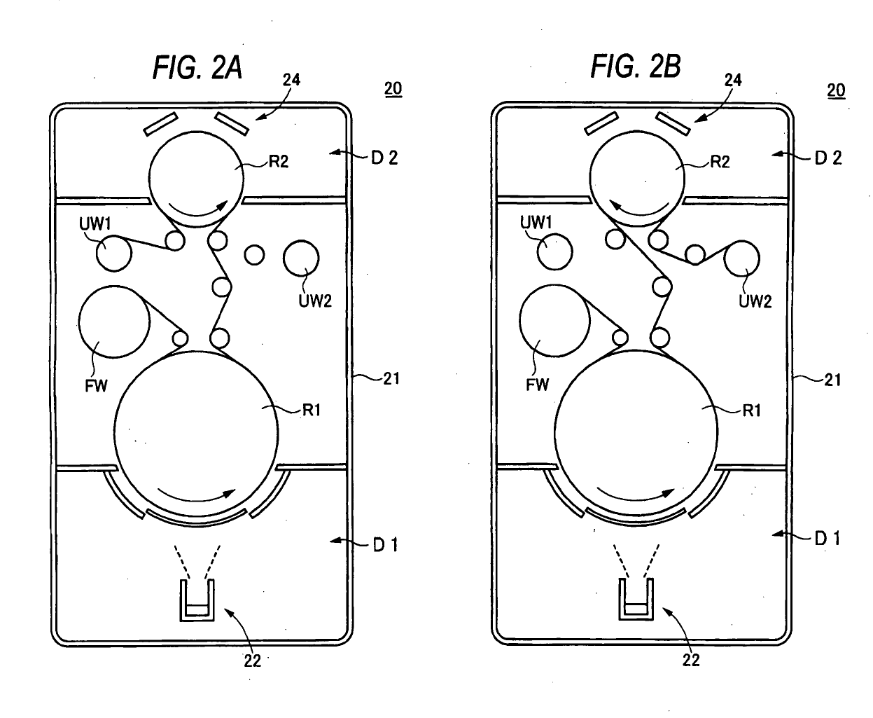

FIGS. 2A and 2B show another example of configuration of the evaporation system. Incidentally, in the following description of the example of configuration, members etc. having the same structures and functions as those of members etc. already described are referred to by the same or like numerals and signs in the drawings so that description thereof will be simplified or omitted.

One drive portion FW which is driven to rotate to thereby feed out the substrate film and two drive portions UW1 and UW2 which are driven to rotate to thereby take up the substrate film are provided in the inside of a housing 21 of an evaporation system 20 according to this example of configuration.

Two film-forming rollers R1 and R2 are further provided in the evaporation system 20. The film-forming roller R1 is partially located in the inside of an evaporation chamber D1. An evaporation portion 22 is provided in the inside of the evaporation chamber D1. The substrate film is conveyed while supported by the film-forming roller R1, so that the evaporation portion 22 in the inside of the evaporation chamber D1 forms an evaporation film on a surface of the substrate film opposite to the surface supported by the film-forming roller R1.

The film-forming roller R2 is disposed vertically above the film-forming roller R1. That is, the evaporation system 20 has a so-called vertical structure in which the two film-forming rollers R1 and R2 are disposed vertically in an upper portion and a lower portion of the evaporation system 20 respectively. The film-forming roller R2 is partially located in the inside of an evaporation chamber D2. An evaporation portion 24 is provided in the inside of the evaporation chamber D2. The evaporation portion 24 performs sputtering or CVD film-forming. The substrate film is conveyed while supported by the film-forming roller R2, so that the evaporation portion 24 in the inside of the evaporation chamber D2 forms an evaporation film on a surface of the substrate film opposite to the surface supported by the film-forming roller R2.

FIG. 2A shows a state in which evaporation is made twice on a single surface of the substrate film. Specifically, the drive portion FW is driven to rotate to thereby feed out the substrate film along the conveyance path. The substrate film is taken up by the drive portion UW1. On this occasion, the drive portion UW2 is not driven to rotate at all or is driven to rotate in such a range as to exert no influence on the conveyed substrate film. One surface of the substrate film is supported by the film-forming roller R1, so that the evaporation portion 22 in the evaporation chamber D1 forms an evaporation film on a surface of the substrate film opposite to the surface supported by the film-forming roller R1.

Then, the surface of the substrate film supported by the film-forming roller R1 is supported by the film-forming roller R2. A surface of the substrate film opposite to the surface supported by the film-forming roller R1 is used as a target surface of evaporation so that the evaporation portion 24 in the evaporation chamber D2 forms an evaporation film on the target surface of evaporation. Then, the substrate film is taken up by the drive portion UW1.

The evaporation system 20 according to this example of configuration can perform control to select either evaporation on both surfaces of the substrate film or evaporation on a single surface of the substrate film in accordance with change-over to either of the drive portions UW1 and UW2.

By conveying the substrate film as shown in FIG. 2A, evaporation can be made twice on a single surface of the substrate film.

For example, a film containing a metal or a metal compound (such as metal oxide or metal nitride) can be vapor-deposited on a surface of the substrate film by the evaporation portion 22, and a film containing an organic material can be further vapor-deposited on the surface of the substrate film by the evaporation portion 24.

FIG. 2B shows a state in which evaporation is made on both surfaces of the substrate film. Specifically, the drive portion FW is driven to rotate to thereby feed out the substrate film along the conveyance path. The substrate film is taken up by the drive portion UW2. On this occasion, the drive portion UW1 is not driven to rotate at all or is driven to rotate in such a range as to exert no influence on the conveyed substrate film. One surface of the substrate film is supported by the film-forming roller R1, so that the evaporation portion 22 in the evaporation chamber D1 forms an evaporation film on a surface of the substrate film opposite to the surface supported by the film-forming roller R1.

Then, the surface of the substrate film supported by the film-forming roller R1 is used as a target surface of evaporation by the film-forming roller R2 so that the evaporation portion 24 in the evaporation chamber D2 forms an evaporation film on the target surface of evaporation. Then, the substrate film is taken up by the drive portion UW2.

By conveying the substrate film as shown in FIG. 2B, evaporation can be made on both surfaces of the substrate film.

For example, films each containing a metal or a metal compound (such as metal oxide or metal nitride) can be vapor-deposited on both surfaces of the substrate film by the evaporation portions 22 and 24 respectively.

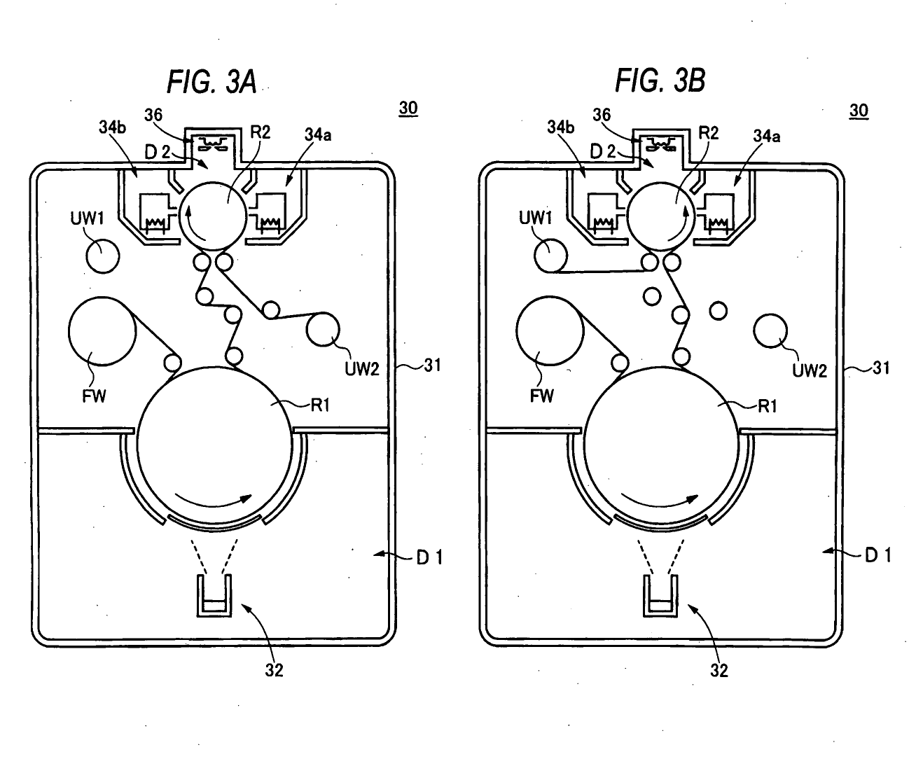

FIGS. 3A and 3B show another example of configuration of the evaporation system.

One drive portion FW which is driven to rotate to thereby feed out the substrate film and two drive portions UW1 and UW2 which are driven to rotate to thereby take up the substrate film are provided in the inside of a housing 31 of an evaporation system 30 according to this example of configuration.

Two film-forming rollers R1 and R2 are further provided in the evaporation system 30. The film-forming roller R1 is partially located in the inside of an evaporation chamber D1. An evaporation portion 32 is provided in the inside of the evaporation chamber D1. The substrate film is conveyed while supported by the film-forming roller R1, so that the evaporation portion 32 in the inside of the evaporation chamber D1 forms an evaporation film on a surface of the substrate film opposite to the surface supported by the film-forming roller R1.

The film-forming roller R2 is disposed vertically above the film-forming roller R1. The film-forming roller R2 is partially located in the inside of an evaporation chamber D2. Two evaporation portions 34a and 34b disposed side by side along the conveyance path and a curing portion 36 located between the two evaporation portions 34a and 34b in the conveyance path are provided in the inside of the evaporation chamber D2.

The evaporation portions 34a and 34b vapor-deposit a film on a surface of the substrate film by vaporizing or sublimating a polymeric organic compound (monomer).

The curing portion 36 irradiates a surface of the substrate film with ultraviolet rays or electron beams for curing to thereby cure the polymeric organic compound vapor-deposited on the surface of the substrate film. For example, an EB gun can be used as the curing portion.

FIG. 3A shows a state in which evaporation is made on both surfaces of the substrate film. Specifically, the drive portion FW is driven to rotate to thereby feed out the substrate film along the conveyance path. The substrate film is taken up by the drive portion UW2. On this occasion, the drive portion UW1 is not driven to rotate at all or is driven to rotate in such a range as to exert no influence on the conveyed substrate film. One surface of the substrate film is supported by the film-forming roller R1. A surface of the substrate film opposite to the surface supported by the film-forming roller R1 is used as a target surface of evaporation so that the evaporation portion 32 in the evaporation chamber D1 forms an evaporation film on the target surface of evaporation.

The substrate film is then supported by the film-forming roller R2 and the same surface as supported by the film-forming roller R1 is used as a target surface of evaporation so that the evaporation portions 34a and 34b in the evaporation chamber D2 form an evaporation film on the target surface of evaporation. Then, the substrate film is taken up by the drive portion UW2. On this occasion, after evaporation is made by one of the two evaporation portions 34a and 34b, that is, by the evaporation portion 34b disposed on the upstream side of the conveyance path, curing is applied by the curing portion 36 on the downstream side. Driving of the evaporation portion 34a may be stopped so that evaporation is not made by the evaporation portion 34a. It is possible to change the order of the evaporation in R1 and R2 by changing the direction of film driving.

By conveying the substrate film as shown in FIG. 3A, evaporation can be made on both surfaces of the substrate film.

For example, films each containing a metal or a metal compound (such as metal oxide or metal nitride) can be vapor-deposited on both surfaces of the substrate film respectively by the evaporation portion 32 and the evaporation portion 34b. Or, for example, before such films each containing a metal or a metal compound are formed, films each containing an organic material may be vapor-deposited on both surfaces of the substrate film respectively by the evaporation portion 32 and the evaporation portion 34b.

FIG. 3B shows a state in which evaporation is made twice on a single surface of the substrate film. Specifically, the drive portion FW is driven to rotate to thereby feed out the substrate film along the conveyance path. The substrate film is taken up by the drive portion UW1. On this occasion, the drive portion UW2 is not driven to rotate at all or is driven to rotate in such a range as to exert no influence on the conveyed substrate film. One surface of the substrate film is supported by the film-forming roller R1. A surface of the substrate film opposite to the surface supported by the film-forming roller R1 is used as a target surface of evaporation so that the evaporation portion 32 in the evaporation chamber D1 forms an evaporation film on the target surface of evaporation.

The substrate film is then supported by the film-forming roller R2 and a surface of the substrate film opposite to the surface supported by the film-forming roller R1 is used as a target surface of evaporation so that the evaporation portion 34a in the evaporation chamber D2 forms an evaporation film on the target surface of evaporation. Then, the substrate film is taken up by the drive portion UW1. On this occasion, after evaporation is made by one of the two evaporation portions 34a and 34b, that is, by the evaporation portion 34a disposed on the upstream side of the conveyance path, curing is applied by the curing portion 36 on the downstream side. Driving of the evaporation portion 34b may be stopped so that evaporation is not made by the evaporation portion 34b.

By conveying the substrate film as shown in FIG. 3B, evaporation can be made twice on a single surface of the substrate film.

For example, films each containing a metal or a metal compound (such as metal oxide or metal nitride) can be laminated on a single surface of the substrate film by the evaporation portion 32 and the evaporation portion 34a. Or, for example, before such films each containing a metal or a metal compound are formed, films each containing an organic material may be laminated on the single surface of the substrate film by the evaporation portion 32 and the evaporation portion 34a.

Next, control systems for the evaporation system will be described.

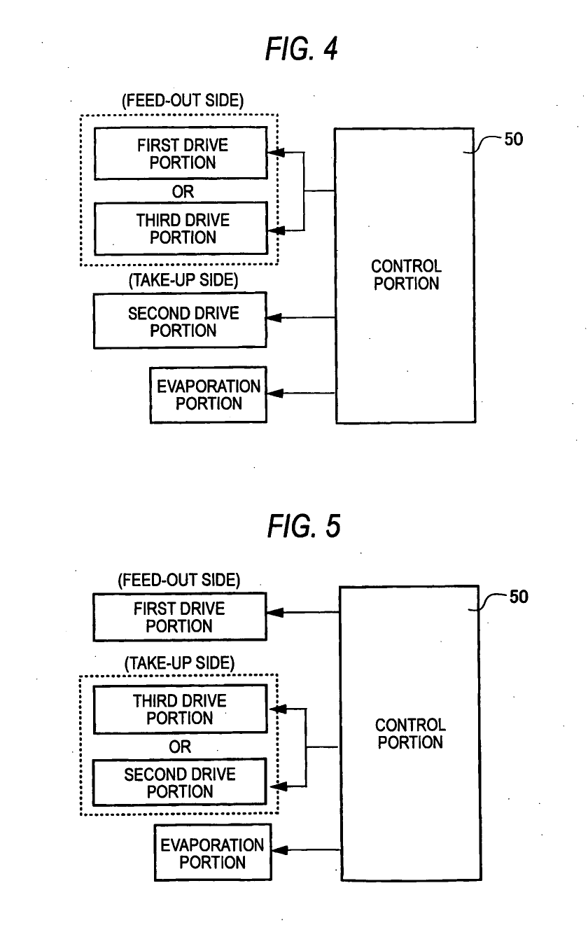

A control system for the evaporation system shown in FIG. 4 corresponds to the configuration example shown in FIGS. 1A and 1B. The control system has a first drive portion which is driven to rotate to thereby feed out the substrate film, and a second drive portion which is driven to rotate to thereby take up the substrate film. The first drive portion corresponds to the drive portion FW1 in the evaporation system shown in FIGS. 1A and 1B. The second drive portion corresponds to the drive portion UW in the evaporation system shown in FIGS. 1A and 1B. The control system further has a third drive portion which can be drive-controlled while the first drive portion is changed over to the third drive portion. The third drive portion corresponds to the drive portion FW2 in the evaporation system shown in FIGS. 1A and 1B. The first, second and third drive portions can be drive-controlled respectively independently by a control portion 50. The control portion 50 further controls an evaporation portion at the time of evaporation.

The control portion 50 enables either evaporation on both surfaces of the substrate film or evaporation on a signal surface of the substrate film by driving either of the first drive portion and the third drive portion on a feed-out side.

A control system for the evaporation system shown in FIG. 5 corresponds to the configuration example shown in FIGS. 2A and 2B or FIGS. 3A and 3B. The control system has a first drive portion which is driven to rotate to thereby feed out the substrate film, and a second drive portion which is driven to rotate to thereby take up the substrate film. The first drive portion corresponds to the drive portion FW in the evaporation system shown in FIGS. 2A and 2B or FIGS. 3A and 3B. The second drive portion corresponds to the drive portion UW1 in the evaporation system shown in FIGS. 2A and 2B or FIGS. 3A and 3B. The control system further has a third drive portion which can be drive-controlled while the second drive portion is changed over to the third drive portion. The third drive portion corresponds to the drive portion UW2 in the evaporation system shown in FIGS. 2A and 2B or FIGS. 3A and 3B. The first, second and third drive portions can be drive-controlled respectively independently by a control portion 50. The control portion 50 further controls an evaporation portion at the time of evaporation.

The control portion 50 enables either evaporation on both surfaces of the substrate film or evaporation on a signal surface of the substrate film by driving either of the second drive portion and the third drive portion on a take-up side.

As described above, the evaporation system is controlled by the control portion 50 so that two drive portions (which may include the third drive portion) are selected from three drive portions in accordance with the direction of the target surface of the substrate film to be subjected to evaporation and evaporation is made on the substrate film in accordance with the conveyance path defined by the selected two drive portions.

When control can be made so that the first drive portion is changed over to the third drive portion and vice versa, evaporation can be made on a single surface of the substrate film while the substrate film is conveyed so that the substrate film is fed out from the first drive portion and taken up by the second drive portion, and evaporation can be made on both surfaces of the substrate film while the substrate film is conveyed so that the substrate film is fed out from the third drive portion and taken up by the second drive portion. In this manner, the conveyance path is changed to select either evaporation on both surfaces of the substrate film or evaporation on a single surface of the substrate film in accordance with whether change-over to the third drive portion from the first drive portion is made or not. By changing over the drive portion in this manner, either evaporation on both surfaces of the substrate film or evaporation on a desired signal surface of the substrate film can be selected without the necessity of changing the locations of the film-forming, rolls and the evaporation portions. According to the invention, it is therefore possible to avoid increase in size and complication of the evaporation system, so that increase in equipment cost can be prevented.

Incidentally, the invention is not limited to the aforementioned embodiments and various changes, modifications, etc. may be made suitably.

Although the configuration examples have been described in the case where two film-forming rollers and two evaporation portions are provided, three or more film-forming rollers and three or more evaporation portions may be provided.

This specification discloses the following items.

(1) An evaporation system for forming evaporation films on a substrate film, including:

a first drive portion which is driven to rotate to thereby feed out the substrate film;

a second drive portion which is driven to rotate to thereby take up the substrate film conveyed to the second drive portion;

film-forming rollers which are provided on a conveyance path of the substrate film conveyed between the first drive portion and the second drive portion and which support one surface of the substrate film onto circumferential surfaces of the film-forming rollers;

evaporation portions which form the evaporation films on a surface of the substrate film opposite to the surface supported by the film-forming rollers; and

a third drive portion which is driven while either of the first drive portion and the second drive portion is changed over to the third drive portion so that the conveyance path is changed to select either of evaporation on both surfaces of the substrate film and evaporation on a single surface of the substrate film in accordance with whether change-over to the third drive portion is made or not.

(2) An evaporation system according to the item (1), wherein the evaporation portions include a first evaporation portion, and a second evaporation portion which performs evaporation on a surface of the substrate film subjected to the first evaporation portion or an opposite surface of the substrate film.
(3) An evaporation system according to the item (2), wherein the second evaporation portion is provided vertically above the first evaporation portion.
(4) An evaporation system according to the item (3), wherein the second evaporation portion has evaporation sources provided on the path of conveyance of the substrate film, and a curing portion disposed between the evaporation sources on the path of conveyance of the substrate film so as to irradiate the evaporation films with ultraviolet rays or electron beams to cure the evaporation films.
(5) An evaporation system according to the item (3), wherein the second evaporation portion performs sputtering or CVD film-forming on the substrate film.
(6) An evaporation system according to any one of the items (1) to (5), wherein each of the evaporation films contains a metal or a metal compound.
(7) An evaporation system according to any one of the items (1) to (6), wherein a film containing a metal or a metal compound and a film containing an organic material are laminated successively on one surface of the substrate film.
(8) An evaporation system according to any one of the items (1) to (6), wherein a polymeric organic compound is evaporated on one surface of the substrate film.

What is claimed is:

1. An evaporation system for forming evaporation films on a substrate film, comprising:
a first drive portion which is driven to rotate to thereby feed out the substrate film;
a second drive portion which is driven to rotate to thereby take up the substrate film conveyed to the second drive portion;
film-forming rollers which are provided on a conveyance path of the substrate film conveyed between the first drive portion and the second drive portion and which support one surface of the substrate film onto circumferential surfaces of the film-forming rollers;
evaporation portions which form the evaporation films on a surface of the substrate film opposite to the surface supported by the film-forming rollers; and
a third drive portion which is driven while either of the first drive portion and the second drive portion is changed over to the third drive portion so that the conveyance path is changed to select either of evaporation on both surfaces of the substrate film and evaporation on a single surface of the substrate film in accordance with whether change-over to the third drive portion is made or not.

2. The evaporation system according to claim 1, wherein the evaporation portions comprise a first evaporation portion, and a second evaporation portion which performs evaporation on a surface of the substrate film subjected to the first evaporation portion or an opposite surface of the substrate film.

3. The evaporation system according to claim 2, wherein the second evaporation portion is provided vertically above the first evaporation portion.

4. The evaporation system according to claim 3, wherein the second evaporation portion has evaporation sources provided on the path of conveyance of the substrate film, and a curing portion disposed between the evaporation sources on the path of conveyance of the substrate film so as to irradiate the evaporation films with ultraviolet rays or electron beams to cure the evaporation films.

5. The evaporation system according to claim 3, wherein the second evaporation portion performs sputtering or CVD film-forming on the substrate film.

6. The evaporation system according to claim 1, wherein at least one of the evaporation films comprises a metal or a metal compound.

7. The evaporation system according to claim 2, wherein at least one of the evaporation films comprises a metal or a metal compound.

8. The evaporation system according to claim 3, wherein at least one of the evaporation films comprises a metal or a metal compound.

9. The evaporation system according to claim 4, wherein at least one of the evaporation films comprises a metal or a metal compound.

10. The evaporation system according to claim 1, wherein a film comprising a metal or a metal compound and a film comprising an organic material are laminated successively on one surface of the substrate film.

11. The evaporation system according to claim 2, wherein a film comprising a metal or a metal compound and a film comprising an organic material are laminated successively on one surface of the substrate film.

12. The evaporation system according to claim 3, wherein a film comprising a metal or a metal compound and a film comprising an organic material are laminated successively on one surface of the substrate film.

13. The evaporation system according to claim wherein a film comprising a metal or a metal compound and a film comprising an organic material are laminated successively on one surface of the substrate film.

14. The evaporation system according to claim 1, wherein a polymeric organic compound is evaporated on one surface of the substrate film.

15. The evaporation system according to claim 2, wherein a polymeric organic compound is evaporated on one surface of the substrate film.

16. The evaporation system according to claim 3, wherein a polymeric organic compound is evaporated on one surface of the substrate film.

17. The evaporation system according to claim 4, wherein a polymeric organic compound is evaporated on one surface of the substrate film.
